(19) United States
(12) Patent Application Publication
(10) Pub. No.: US 2025/0273615 A1
(43) Pub. Date: Aug. 28, 2025

(54) POWER MODULE

(71) Applicants: Hyundai Motor Company, Seoul (KR); Kia Corporation, Seoul (KR)

(72) Inventors: Han Jin DO, Incheon (KR); Sung Won PARK, Incheon (KR); Jin Myeong YANG, Seongnam-Si (KR); Hyun Koo LEE, Seoul (KR)

(73) Assignees: Hyundai Motor Company, Seoul (KR); Kia Corporation, Seoul (KR)

(21) Appl. No.: 18/938,720

(22) Filed: Nov. 6, 2024

(30) Foreign Application Priority Data
Feb. 22, 2024 (KR) 10-2024-0025656

(51) Int. Cl. H01L 23/00; H01L 23/373; H01L 25/07

(52) U.S. Cl. CPC H01L 24/26; H01L 23/3735; H01L 24/32; H01L 25/072; H01L 2224/26122; H01L 2224/26152; H01L 2224/32227; H01L 2924/30107

(57) ABSTRACT

A power module includes an upper substrate, a lower substrate, a first semiconductor chip, a first spacer electrically interconnecting a first metal layer of the upper substrate and a second metal layer of the lower substrate, a second spacer electrically interconnecting the first semiconductor chip and the first metal layer, and a first connection layer configured to form a current path, and a power lead.

### CROSS-REFERENCE TO RELATED APPLICATION

The present application claims priority to Korean Patent Application No. 10-2024-0025656 filed on Feb. 22, 2024, the entire contents of which is incorporated herein for all purposes by this reference.

### BACKGROUND OF THE PRESENT DISCLOSURE

### Field of the Present Disclosure

The present disclosure relates to a power module, and in particular, to a power module configured for achieving an enhancement in operation efficiency through additional disposition of a connection layer between an upper substrate and a lower substrate.

### DESCRIPTION OF RELATED ART

In pace with recently increased interest in the environment, use of an ecofriendly vehicle equipped with an electric motor as a power source is increasing. Such an ecofriendly vehicle is also referred to as an “electrified vehicle”. As representative examples of the electrified vehicle, there are an electric vehicle (EV) and a hybrid electric vehicle (HEV).

Such an electrified vehicle is equipped with an inverter configured to convert DC power into AC power while driving of a motor. Typically, the inverter is constituted by one or plural power modules including a semiconductor chip configured to perform a switching function.

Meanwhile, the semiconductor chip, which is configured to perform a switching function and is provided at a power module, as mentioned above, may generate heat because large current at high voltage flows through the power module during operation of the power module. For stable operation of the power module, it is necessary to eliminate generation of heat. To the present end, various methods are applied.

In accordance with a cooling method applied thereto, the power module may be classified into a single-side cooling type in which heat generated from the semiconductor chip is transferred to one of an upper substrate and a lower substrate, to dissipate the generated heat, and a double-sided cooling type in which heat generated from the semiconductor chip is transferred to both the upper substrate and the lower substrate in a distributed manner, to dissipate the generate heat.

In the double-sided cooling type power module, the size and electrical characteristics of the power module have great influence on reliability. That is, when the power module has a reduced size and excellent electrical characteristics, reliability thereof is enhanced.

Meanwhile, as output requirement specifications for an inverter gradually become higher, the inverter should operate to support a high output, and accordingly, an amount of heat generated from a semiconductor chip of the inverter increases. To cope with the increased heat amount, main parts of the inverter including the semiconductor chip, a substrate, etc. are also increased in size.

As the size of such a power module increases, a current loop of the power module becomes long and complex. As a result, there may be a problem in reliability, for example, degradation in electrical characteristics, generation of substrate bending, or the like. Therefore, a scheme capable of solving such a problem should be proposed.

The information included in the present Background of the present disclosure is only for enhancement of understanding of the general background of the present disclosure and may not be taken as an acknowledgement or any form of suggestion that the present information forms the prior art already known to a person skilled in the art.

### BRIEF SUMMARY

Various aspects of the present disclosure are directed to providing a power module configured for enhancing a current overlap effect while simplifying a current loop through additional disposition of a connection layer between an upper substrate and a lower substrate.

Objects of the present disclosure are not limited to the above-described objects, and other objects of the present objects not yet described will be more clearly understood by those skilled in the art from the following detailed description.

In accordance with an aspect of the present disclosure, the above and other objects may be accomplished by the provision of a power module including an upper substrate including a first metal layer, a lower substrate disposed under the upper substrate, the lower substrate including a second metal layer facing the first metal layer, a first semiconductor chip disposed on the second metal layer, a first spacer electrically interconnecting the first metal layer and the second metal layer while extending vertically, a second spacer electrically interconnecting the first semiconductor chip and the first metal layer while extending vertically, a first connection layer configured to form a current path between the upper substrate and the lower substrate and between the first spacer and the second spacer in a direction crossing a direction of a current path formed by the first spacer and the second spacer, and a power lead disposed at at least one of the first metal layer and the second metal layer.

The first connection layer may not overlap with the first spacer and the second spacer in a plane.

The first connection layer may allow penetration of at least one of the first spacer and the second spacer therethrough.

The first connection layer may be provided with at least one of a first through hole including a planar area corresponding to a planar area of the first spacer and through which the first spacer is penetrated and a second through hole including a planar area corresponding to a planar area of the second spacer and through which the second spacer is penetrated.

At least one of the first spacer and the second spacer may be divided into an upper portion and a lower portion. The first connection layer may be disposed to interconnect the upper portion and the lower portion of the at least one of the first spacer and the second spacer between the upper portion and the lower portion.

The first connection layer may form, through a pattern formed on a plane, the current path in the direction crossing the direction of the current path formed by the first spacer and the second spacer.

The pattern may be formed through a combination of a plurality of separated panels disposed in parallel while being horizontally spaced from one another.

The first connection layer may include a vertical thickness greater than or equal to a vertical thickness of the power lead.

The first connection layer may include a substrate-corresponding portion overlapping with the upper substrate and the lower substrate at at least a portion thereof in a plane, and a lead-corresponding portion extending from the substrate-corresponding portion to protrude outwardly of the upper substrate and the lower substrate in the plane. The lead-corresponding portion may allow current to be input thereto and to be output therefrom.

The lead-corresponding portion may include one of a positive terminal, a negative terminal, and an output terminal or may be connected to one of the positive terminal, the negative terminal, and the output terminal. The power lead may include one of remaining ones of the positive terminal, the negative terminal, and the output terminal.

The power module may further include a second connection layer disposed to be vertically spaced from the first connection layer and configured to form a current path between the upper substrate and the lower substrate and between the first spacer and the second spacer in the direction crossing the direction of the current path formed by the first spacer and the second spacer. The second connection layer may include another one of the remaining ones of the positive terminal, the negative terminal, and the output terminal or may be connected to the other one of the remaining ones of the positive terminal, the negative terminal, and the output terminal.

The lead-corresponding portion may be upwardly spaced from the power lead to overlap with the power lead in a plane.

The lead-corresponding portion may be bent downwardly from the substrate-corresponding portion and extends outwardly of the upper substrate and the lower substrate so that the lead-corresponding portion is disposed in parallel to the power lead while being horizontally spaced from the power lead.

The substrate-corresponding portion may be disposed in parallel to the upper substrate and the lower substrate while being vertically spaced from the upper substrate and the lower substrate.

The power module may further include a third spacer disposed to be horizontally spaced from the second spacer when the first spacer is disposed therebetween. The first connection layer may be bonded to at least one of the upper substrate, the lower substrate, the first spacer, the second spacer, and the third spacer.

The first connection layer may not overlap with the third spacer in a plane.

The first connection layer may be bent upwardly or downwardly between the first spacer and the third spacer and bonded to the upper substrate or the lower substrate.

The first connection layer may allow penetration of the third spacer therethrough.

The first connection layer may be horizontally bonded to a side surface of the third spacer.

At least one of the first metal layer and the second metal layer may be formed by a plurality of horizontally-spaced portions. The first connection layer may be extending vertically between the first spacer and the second spacer and electrically connected to at least one of the plurality of portions.

In accordance with various embodiments of the present disclosure as described above, it may be possible to simplify the current loop of the power module through the connection layer additionally disposed between the upper substrate and the lower substrate while including a structure through which the spacers extend.

, furthermore, it may be possible to enhance a current overlap effect through the current loop simplified through the connection layer.

, furthermore, it may be possible to reduce sizes of an insulation pattern and a via spacer for formation of the current loop, achieving a reduction in module size.

Furthermore, it may be possible to enhance reliability of the power module through simplification of the current loop and a reduction in module size.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a plan view of a portion of a power module according to an exemplary embodiment of the present disclosure when viewed in a first-axis direction thereof;

FIG. 2 is a side view of the power module according to the exemplary embodiment of the present disclosure when viewed in a second-axis direction thereof;

FIG. 3A, FIG. 3B, FIG. 3C, FIG. 3D, FIG. 3E, FIG. 3F, and FIG. 3G are views explaining structures of a first connection layer according to various exemplary embodiments of the present disclosure;

FIG. 4, FIG. 5, FIG. 6 and FIG. 7 are views explaining current loops based on different structures of the first connection layer according to various exemplary embodiments of the present disclosure; and

FIG. 8A, FIG. 8B and FIG. 8C are views explaining current loops based on different structures of a first metal layer and a second metal layer according to various exemplary embodiments of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

For embodiments of the present disclosure included herein, specific structural or functional descriptions are exemplary to merely describe the embodiments of the present disclosure, and the embodiments of the present disclosure can be implemented in various forms and should not be interpreted as being limited to the embodiments described in the present specification.

As various modifications can be made and diverse embodiments are applicable to the embodiments according to the concept of the present disclosure, specific embodiments will be illustrated with reference to the accompanying drawings and described in detail herein. However, these specific embodiments should not be construed as limiting the embodiments according to the concept of the present disclosure, but should be construed as extending to all modifications, equivalents, and substitutes included in the concept and technological scope of the present disclosure.

Unless defined otherwise, terms used herein including technological or scientific terms include the include the same meaning as generally understood by those of ordinary skill in the art to which the present disclosure pertains. The terms used herein shall be interpreted not only based on the definition of any dictionary but also the meaning which is used in the field to which the present disclosure pertains, furthermore, unless clearly defined, the terms used herein shall not be interpreted too ideally or formally.

Hereinafter, various exemplary embodiments of the present disclosure will be described in detail with reference to the accompanying drawings, and the same or similar elements are designated by the same reference numerals regardless of the numerals in the drawings and redundant description thereof will be omitted.

Although “module” or “unit” is suffixed to constituent elements described in the following description, this is intended only for ease of description of the specification. The suffixes themselves have no meaning or function to distinguish the constituent element using the suffix from the constituent element using no suffix.

In the following description of the exemplary embodiments of the present disclosure, a detailed description of known functions and configurations incorporated herein will be omitted when it may obscure the subject matter of the exemplary embodiments of the present disclosure, furthermore, the exemplary embodiments of the present disclosure will be more clearly understood from the accompanying drawings and should not be limited by the accompanying drawings, and it is to be appreciated that all changes, equivalents, and substitutes that do not depart from the spirit and technical scope of the present disclosure are encompassed in the present in an exemplary embodiment of the present disclosure.

It will be understood that, although the terms “first”, “second”, etc. may be used herein to describe various elements, these elements should not be limited by these terms. These terms are only used to distinguish one element from another.

In the case where an element is “connected” or “linked” to another element, it should be understood that the element may be directly connected or linked to the other element, or another element may be present therebetween. Conversely, in the case where an element is “directly connected” or “directly linked” to another element, it should be understood that no other element is present therebetween.

Unless clearly used otherwise, singular expressions include a plural meaning.

In the present specification, the term “comprising”, “including”, or the like, is intended to express the existence of the characteristic, the numeral, the step, the operation, the element, the portion, or the combination thereof, and does not exclude another characteristic, numeral, step, operation, element, portion, or any combination thereof, or any addition thereto.

In an exemplary embodiment of the present disclosure, it is provided to simplify a current loop and to increase a current overlap degree through a structure of a power module including a first connection layer configured to form a current path in a direction crossing a direction of a current path formed between an upper substrate and a lower substrate and among a plurality of spacers by the plurality of spacers.

Here, the current loop may be defined as a path along which current input from outside is again output to the outside after passing through constituent elements in the power module, and may be configured through a combination of current paths formed by respective constituent elements of the power module.

The current overlap degree may be increased as the current loop is narrowed. As the current overlap degree increases, the operation efficiency of the power module may be enhanced in accordance with mutual induction.

Meanwhile, expressions such as “upper substrate”, “lower substrate”, “over”, “under”, etc. are intended to represent co-relation, for convenience of understanding, and are not intended to mean absolute directionality.

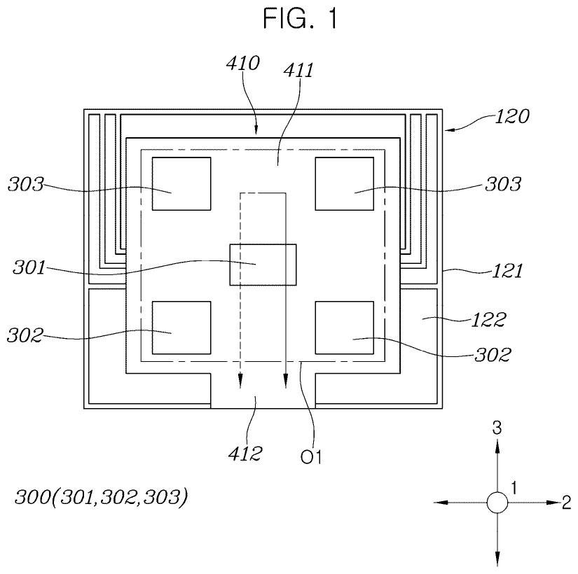

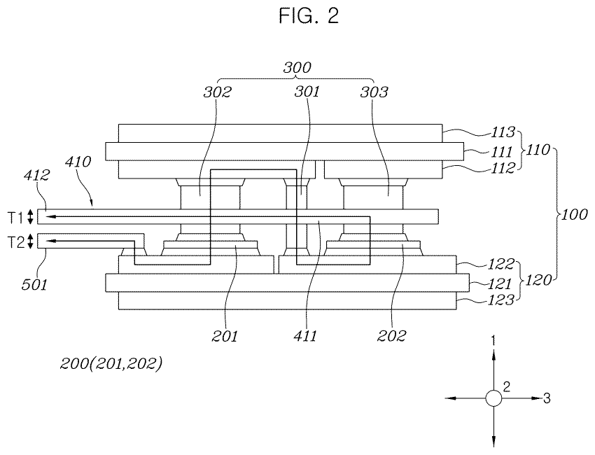

Hereinafter, a configuration and a structure of a power module with an enhanced operation efficiency according to an exemplary embodiment of the present disclosure will be described with reference to FIG. 1 and FIG. 2.

FIG. 1 is a plan view of a portion of a power module according to an exemplary embodiment of the present disclosure when viewed in a first-axis direction. FIG. 2 is a side view of the power module according to the exemplary embodiment of the present disclosure when viewed in a second-axis direction.

In more detail, FIG. 1 represents a figure of a portion of the power module, except for an upper substrate, when downwardly viewed from a top side along a first axis, and FIG. 2 represents a figure of the portion of the power module shown in FIG. 1 in a state in which the upper substrate is added to the power module portion, when viewed at a right side along a second axis.

Referring to both FIG. 1 and FIG. 2, the power module according to the exemplary embodiment of the present disclosure may include an upper substrate 110, a lower substrate 120, a first semiconductor chip 201, a second semiconductor chip 202, first, second, and third spacers 300, a first connection layer 410, and a power lead 501.

FIG. 1 and FIG. 2 mainly show constituent elements associated with the present disclosure, and in practical case, the power module may be implemented to include a greater or smaller number of constituent elements than that of the shown case.

Hereinafter, respective constituent elements as described above and a structure of the power module according to the constituent elements will be described.

First, referring to FIG. 2, the upper substrate 110 includes a first insulating layer 111, and a first metal layer 112 disposed at a lower surface of the first insulating layer 111.

The lower substrate 120 may be disposed under the upper substrate 110 in a first-axis direction while being spaced from the upper substrate 110. The lower substrate 120 includes a second insulating layer 121, and a second metal layer 122 disposed at an upper surface of the second insulating layer 121 while facing the first metal layer 112.

Furthermore, a third metal layer 113 may be disposed at an upper surface of the first insulating layer 111 of the upper substrate 110, and a fourth metal layer 123 may be disposed at a lower surface of the second insulating layer 121 of the lower substrate 120.

The first insulating layer 111 and the second insulating layer 121 may be configured to electrically insulate an inside of the power module from an outside of the power module, and may receive heat generated from the semiconductor chips 201 and 202 via the first metal layer 112 and the second metal layer 122 disposed at the inside of the power module. Furthermore, in the case in which the third metal layer 113 and the fourth metal layer 123 are disposed, the first insulating layer 111 and the second insulating layer 121 may again transfer heat received from the first metal layer 112 and the second metal layer 122 to the third metal layer 113 and the fourth metal layer 123.

The first metal layer 112 and the second metal layer 122 are disposed at the inside of the power module while facing each other, and may establish an electrical connection between the first semiconductor chip 201 and the second semiconductor chip 202 through a pattern thereof.

Meanwhile, the third metal layer 113 and the fourth metal layer 123 may be configured to outwardly dissipate heat transferred thereto, through heat-exchange thereof with outside, cooling the power module. Through the present function, it may be possible to lower an operation temperature of the power module, enabling the power module to operate stably.

Furthermore, for an enhancement in cooling performance of the power module, a cooling channel may be additionally provided outside the third metal layer 113 or the fourth metal layer 123. The cooling channel may be configured in, for example, an air cooling type or a water cooling type. The cooling channel may enhance cooling performance of the power module by enhancing a cooling efficiency thereof through a refrigerant.

Meanwhile, the first to fourth metal layers 112, 122, 113, and 123 may be formed of, for example, copper (Cu), and the first insulating layer 111 and the second insulating layer 121 may be formed of ceramic. In the instant case, the upper substrate 110 and the lower substrate 120 may be implemented by an active metal brazed (AMB) substrate or a direct bonded copper (DBC) substrate.

Meanwhile, the first semiconductor chip 201 may be disposed on the second metal layer 122, and the second semiconductor chip 202 may be disposed on the second metal layer 122 while being spaced apart from the first semiconductor chip 201 in a third-axis direction. Of course, disposition forms of the first semiconductor chip 201 and the second semiconductor chip 202 are not limited to the above-described conditions. For example, the second semiconductor chip 202 may be disposed on the metal layer 112 in a flipped state while also being spaced apart from the first semiconductor chip 201 in the first-axis direction.

Each of the first semiconductor chip 201 and the second semiconductor chip 202 may be turned ON/OFF by a switching signal, and accordingly, whether or not conduction between portions disposed thereover and thereunder may be determined.

Here, the switching signal may be input in a form of a voltage through a signal pad provided at each of the first semiconductor chip 201 and the second semiconductor chip 202. When the switching signal is input, portions disposed over and under each of the first semiconductor chip 201 and the second semiconductor chip 202 are electrically interconnected, and accordingly, current may flow through a power pad provided together with a switching pad.

Meanwhile, for example, each of the first semiconductor chip 201 and the second semiconductor chip 202 may be a switching device such as an insulated gate bipolar transistor (IGBT), a metal-oxide-semiconductor-field-effect transistor (MOSFET), or the like, furthermore, as a material of the first semiconductor chip 201 and the second semiconductor chip 202, silicon (Si) or silicon carbide (SiC) may be used.

Meanwhile, a first one of the spacers 300, that is, a first spacer 301, may extend in a vertical direction (that is, the first-axis direction), and may electrically interconnect the first metal layer 112 and the second metal layer 122, forming a current path to enable current to flow vertically along the first axis. Furthermore, the first spacer 301 may be referred to as a “via spacer”.

A second one of the spacers 300, that is, a second spacer 302, may extend in the vertical direction (that is, the first-axis direction), and may electrically interconnect the first semiconductor chip 201 and the first metal layer 112. The second spacer 302 may be disposed on the power pad of the first semiconductor chip 201, and a planar area thereof may be determined taking into consideration heat transfer efficiency. Similarly to the first spacer 301, the second spacer 302 may form a current path to enable current to flow vertically along the first axis.

Furthermore, a third one of the spacers 300, that is, a third spacer 303, which is spaced from the second spacer 302 in a horizontal direction (the third-axis direction) under the condition that the first spacer 301 is interposed therebetween, while electrically interconnecting the second semiconductor chip 202 and the first metal layer 112, may be included in the power module according to the exemplary embodiment of the present disclosure. Each of the second spacer 302 and the third spacer 303 may also be referred to as a “chip spacer”.

Each of the first spacer 301, the second spacer 302, and the third spacer 303 may be formed of a material including conductivity to electrically interconnect the first metal layer 112, the second metal layer 122, the first semiconductor chip 201, etc.

Meanwhile, the first connection layer 410 may form a current path in a direction crossing a direction of a current path formed between the upper substrate 110 and the lower substrate 120 and between the first spacer 301 and the second spacer 302 by the first spacer 301 and the second spacer 302. For example, the current path formed by the first connection layer 410 may enable current to flow in the horizontal direction (the third-axis direction).

For formation of the above-described current path, the first connection layer 410 may be bonded to at least one of the upper substrate 110, the lower substrate 120, the first spacer 301, the second spacer 302, and the third spacer 303.

The first connection layer 410 may be formed not to overlap with the first spacer 301 and the second spacer 302 in the plane.

In more detail, the first connection layer 410 may allow penetration of at least one of the first spacer 301 and the second spacer 302 therethrough. That is, the first connection layer 410 may allow penetration of at least one of the first spacer 301 and the second spacer 302 therethrough in the first-axis direction.

To the present end, at least one through hole 413 may be provided at the first connection layer 410, and the first connection layer 410 may allow at least one of the first spacer 301 and the second spacer 302 to extend through the at least one through hole 413.

In the instant case, the at least one through hole 413 may include at least one of a first through hole configured to allow penetration of the first spacer 301 therethrough while including a planar area corresponding to the planar area of the first spacer 301, and a second through hole configured to allow penetration of the second spacer 302 therethrough while including a planar area corresponding to the planar area of the second spacer 302.

Meanwhile, for formation of the above-described current path, at least one of the first spacer 301 and the second spacer 302 may be divided into an upper portion and a lower portion, and the first connection layer 410 may be disposed between the upper portion and the lower portion of the at least one of the first spacer 301 and the second spacer 302 to interconnect the upper portion and the lower portion.

For formation of the current path, the first connection layer 410 may be implemented by a portion including conductivity irrespective of the kind thereof, for example, a low temperature co-fired ceramic (LTCC), a printed circuit board (PCB), metal, etc.

As the first connection layer 410 has conductivity and is connected to respective constituent elements of the power module, a current loop of the power module may be formed. In more detail, a current loop may be formed in accordance with connection relations of the first connection layer 410 with the upper substrate 110, the lower substrate 120, the first semiconductor chip 201, the first spacer 301, the second spacer 302, etc.

Furthermore, the first connection layer 410 may form, through a pattern thereof formed on a plane, a current path in a direction crossing the direction of the current path formed by the first spacer 301 and the second spacer 302. The pattern may cut off electrical connection among a plurality of regions in the first connection layer 410, determining electrical connection relations among respective elements. The pattern may also be used as an injection path for a filler in a molding process. Furthermore, the pattern may be formed through a combination of a plurality of separated panels disposed in parallel while being spaced apart from one another in the horizontal direction (that is, the second-axis direction or the third-axis direction).

Furthermore, a thickness T1 of the first connection layer 410 may be greater than or equal to a thickness T2 of the power lead 501. Because large current flows through the first connection layer 410, the first connection layer 410 includes a thickness greater than or equal to the thickness of the power lead 501, through which large current flows, and accordingly, may secure a thickness suitable for flow of large current therethrough.

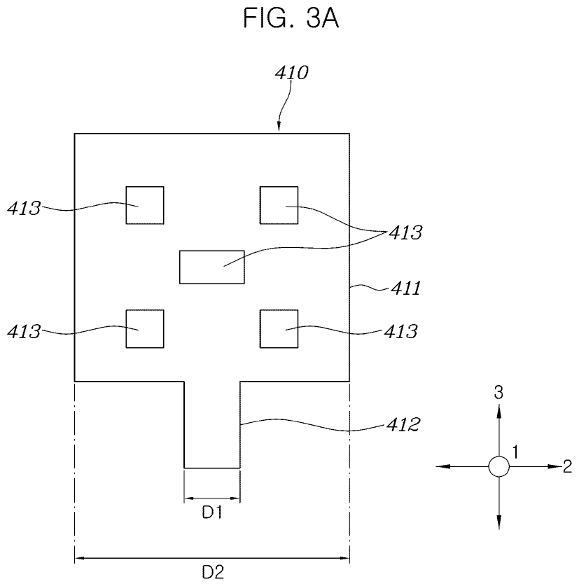

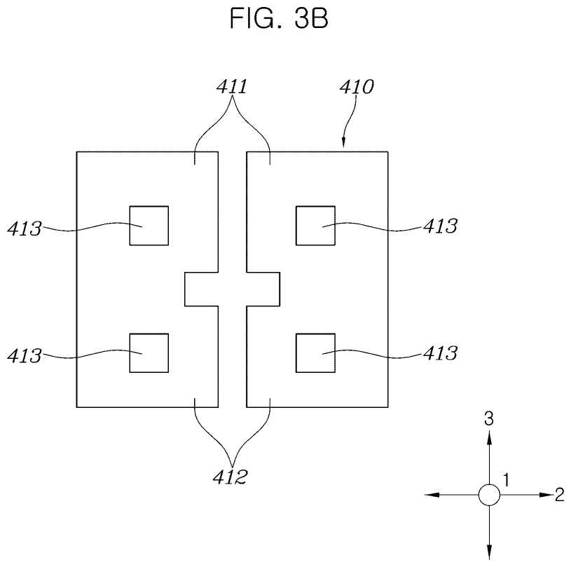

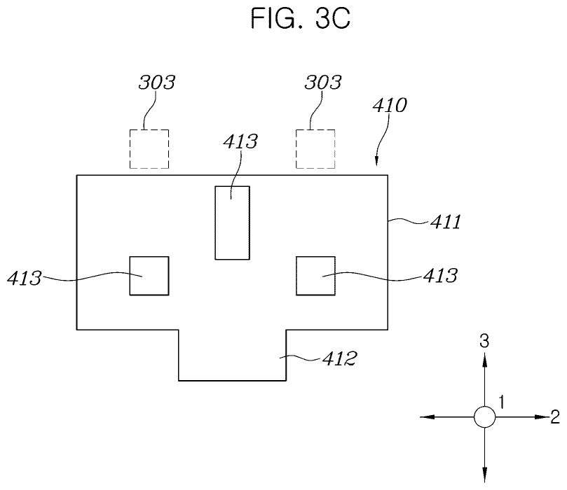

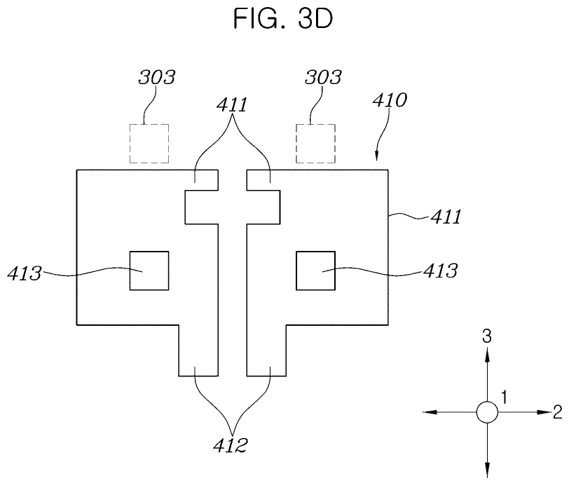

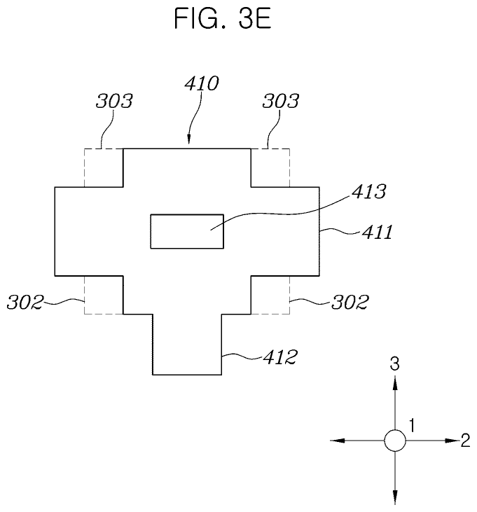

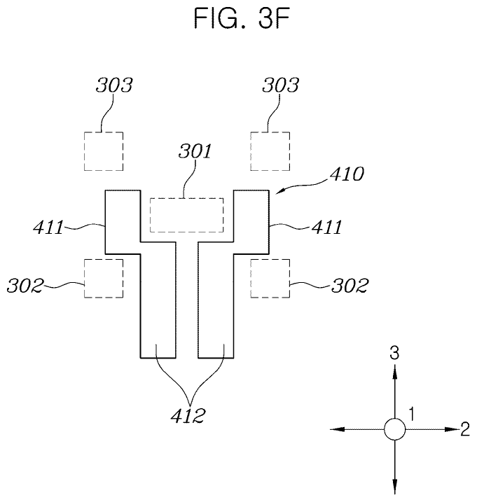

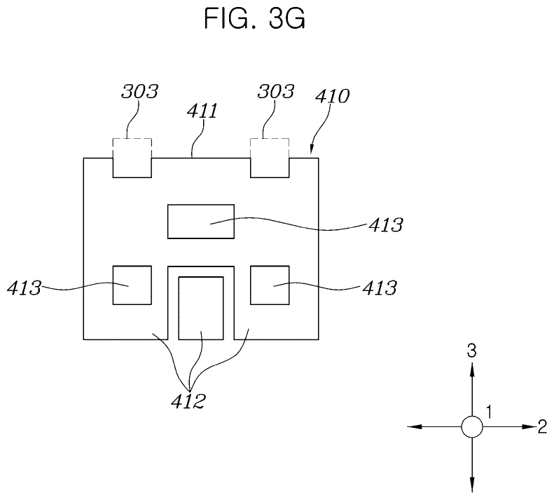

More detailed description of the first connection layer 410 will be provided with reference to FIG. 3A, FIG. 3B, FIG. 3C, FIG. 3D, FIG. 3E, FIG. 3F, and FIG. 3G.

The power lead 501 may be disposed on the second metal layer 122 on which the first semiconductor chip 201 is disposed. Current may be input from outside to the power lead 501 or may be output from the power lead 501 to the outside in accordance with a relation of the power lead 501 with the outside thereof. The power lead 501 may correspond to one of a negative terminal N, a positive terminal P, and an output terminal O.

Meanwhile, an arrow shown in each of FIG. 1 and FIG. 2 represents a flow of current. Through the first connection layer 410, a current loop in which current flows in an order of the power lead 501→the second metal layer 122→the first semiconductor chip 201→the second spacer 302→the first metal layer 112→the first spacer 301→the second metal layer 122→the second semiconductor chip 202→the third spacer 303→the first connection layer 410 or in a reverse order thereof may be formed.

By the current path formed by the first connection layer 410, it is unnecessary for current to flow repeatedly through the first spacer 301 or the second spacer 302. As a result, the whole current loop may be simplified.

Furthermore, as the current loop is narrowed, as shown in FIG. 1, an enhancement in current overlap degree may be achieved. Accordingly, most areas of the first connection layer 410 on a plane may correspond to a current high-overlap region O1. As the current high-overlap region O1 is enlarged, as described above, operation efficiency of the power module may be enhanced.

Meanwhile, detailed structures of power modules according to various exemplary embodiments of the present disclosure may be implemented differently from that of FIG. 2 in accordance with structures of the first connection layer 410. Detailed structures of the first connection layer 410 will be described hereinafter with reference to FIG. 3A, FIG. 3B, FIG. 3C, FIG. 3D, FIG. 3E, FIG. 3F, and FIG. 3G.

FIG. 3A and FIG. 3B are views explaining structures of a first connection layer according to various exemplary embodiments of the present disclosure.

First, referring to FIG. 3A, the first connection layer 410 may include a substrate-corresponding portion 411 and a lead-corresponding portion 412.

The substrate-corresponding portion 411 may overlap, at at least a portion thereof, with the upper substrate 110 and the lower substrate 120 in the plane, and accordingly, may increase a current overlap degree.

In the instant case, a plurality of through holes 413 as described above may be formed at the substrate-corresponding portion 411. The first spacer 301, the second spacer 302, the third spacer 303, etc. may extend through the substrate-corresponding portion 411 along the plurality of through holes 413, respectively.

The lead-corresponding portion 412 may extend from the substrate-corresponding portion 411 to protrude outwardly of the upper substrate 110 and the lower substrate 120 in the plane. Current may be input to and output from the lead-corresponding portion 412. Furthermore, a horizontal width D1 of the lead-corresponding portion 412 may be smaller than a horizontal width D2 of the substrate-corresponding portion 411.

The lead-corresponding portion 412 may include one of a positive terminal, a negative terminal, and an output terminal or may be connected to one of the positive terminal, the negative terminal, and the output terminal. In the instant case, the power lead 501 may include one of the remaining ones of the positive terminal, the negative terminal, and the output terminal.

Meanwhile, although the lead-corresponding portion 412 may be disposed to be upwardly spaced from the power lead 501 so that the lead-corresponding portion 412 overlaps with the power lead 501 in the plane, as shown in FIG. 2, the position relation between the lead-corresponding portion 412 and the power lead 501 is not limited to the above-described condition, and the lead-corresponding portion 412 may be disposed in parallel with the power lead 501 while being spaced from the power lead 501 in the horizontal direction.

Referring to FIG. 3B, the first connection layer 410 may be implemented by a plurality of separated panels, differently from that of FIG. 3A. In the instant case, the first spacer 301, the second spacer 302, and the third spacer 303 may extend through the first connection layer 410 not only along the through holes 413, but also along spaces among the plurality of panels.

Referring to FIGS. 3C and 3D, the third spacer 303 may not extend through the first connection layer 410, in particular, the substrate-corresponding portion 411, differently from those of FIG. 3A and FIG. 3B. That is, the first connection layer 410 may not overlap with the third spacer 301 in the plane.

In the instant case, the substrate-corresponding portion 411 may be bonded to one of a side surface of the third spacer 303, a lower surface of the upper substrate 110, and an upper surface of the lower substrate 120. Furthermore, even when the third spacer 303 does not extend through the first connection layer 410, as shown in FIG. 3D, the first connection layer 410 may be implemented by a plurality of separated panels.

Referring to FIG. 3E, not only the third spacer 303, but also the second spacer 302, may not extend through the first connection layer 410. For the present structure, the planar shape of the first connection layer 410 may be determined taking into consideration disposition of the second spacer 302 and the third spacer 303.

Referring to FIG. 3F, any of the first spacer 301, the second spacer 302, and the third spacer 303 may not pass through the first connection layer 410. For the present structure, the planar shape of the first connection layer 410 may be determined taking into consideration disposition of the first spacer 301, the second spacer 302, and the third spacer 303.

Referring to FIG. 3G, the lead-corresponding portion 412 may include separated portions, and the separated portions may function as a negative terminal, an output terminal, and a positive terminal, respectively.

Any structure different from those of the exemplary embodiments of FIG. 3A, FIG. 3B, FIG. 3C, FIG. 3D, FIG. 3E, FIG. 3F, and FIG. 3G may be applied to a structure of the first connection layer 410 when the structure may form a current path in a direction crossing a direction of a current path formed between the first spacer 301 and the second spacer 302 by the first spacer 301 and the second spacer 302.

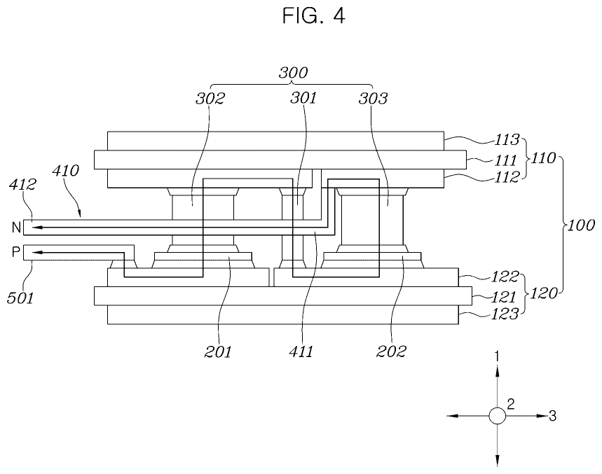

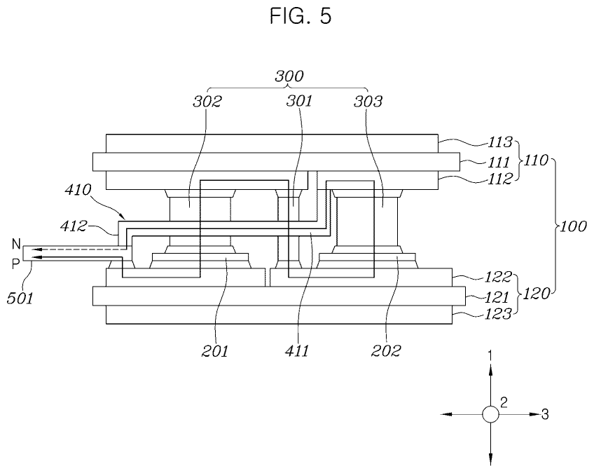

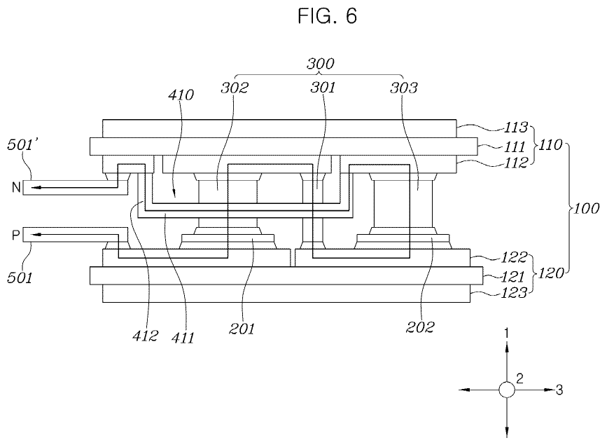

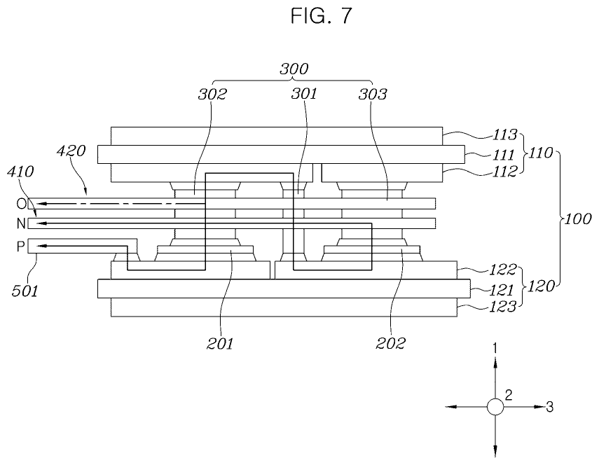

Hereinafter, a current loop of the power module according to a structure of the first connection layer 410 will be described with reference to FIG. 4, FIG. 5, FIG. 6, and FIG. 7.

FIG. 4, FIG. 5, FIG. 6 and FIG. 7 are views explaining current loops based on different structures of the first connection layers according to various exemplary embodiments of the present disclosure, respectively.

In more detail, FIG. 4 and FIG. 5 show embodiments in the case in which the lead-corresponding portion 412 includes a negative terminal N, and the power lead 501 is implemented by a positive terminal P, respectively. FIG. 6 shows an exemplary embodiment in the case in which the lead-corresponding portion 412 is connected to a negative terminal N, and the power lead 501 is implemented by a positive terminal P. FIG. 7 shows an exemplary embodiment in the case in which a second connection layer 420 is disposed together with the first connection layer 410.

First, referring to FIG. 4 and FIG. 5, the first connection layer 410 may form a portion of a current loop including the lead-corresponding portion 412 and the power lead 501 as opposite end portions thereof, respectively.

In the instant case, as shown in FIG. 4, the lead-corresponding portion 412 may be disposed to be upwardly spaced from the power lead 501 so that the lead-corresponding portion 412 overlaps with the power lead 501 in the plane. Through such disposition, current overlap degree may be further enhanced.

Differently from the exemplary embodiment of FIG. 4, as shown in FIG. 5, the lead-corresponding portion 412 may be disposed in parallel to the power lead 501 while being horizontally spaced from the power lead 501. For the present disposition, the lead-corresponding portion 412 may be downwardly bent from the substrate-corresponding portion 411 and may then extend outwardly of the upper substrate 110 and the lower substrate 120.

Meanwhile, the substrate-corresponding portion 411 may be bent upwardly between the first spacer 301 and the third spacer 303 and bonded to the upper substrate 110.

In accordance with the above-described structures, a current loop in which current flows in an order of the power lead 501→the second metal layer 122→the first semiconductor chip 201→the second spacer 302→the first metal layer 112→the first spacer 301→the second metal layer 122→the second semiconductor chip 202→the third spacer 303→the first metal layer 122→the first connection layer 410 or in a reverse order thereof may be formed.

Meanwhile, differently from those of FIG. 4 and FIG. 5, the lead-corresponding portion 412 may include a positive terminal P or may be connected to the positive terminal P. In the instant case, the substrate-corresponding portion 411 may be bent downwardly between the first spacer 301 and the third spacer 303 and bonded to the lower substrate 110.

In the instant case, a current loop in which current flows in an order of the power lead 501→the second metal layer 122→the first semiconductor chip 201→the second spacer 302→the first metal layer 112→the first spacer 301→the second metal layer 122→the second semiconductor chip 202→the third spacer 303→the first metal layer 122→the first connection layer 410 or in a reverse order thereof may be formed.

Referring to FIG. 6, the power lead 501 and another power lead 501′ may be provided at the second metal layer 122 and the first metal layer 112, respectively. In the instant case, the lead-corresponding portion 412 of the first connection layer 410 may be bent upwardly from the substrate-corresponding portion 411 and bonded to the first metal layer 112, accordingly, may be connected to the power lead 501′ provided at the first metal layer 112.

The substrate-corresponding portion 411 may be extended upwards between the first spacer 301 and the third spacer 303 and bonded to the second metal layer 122.

In accordance with the above-described structure, a current loop in which current flows in an order of the power lead 501→the second metal layer 122→the first semiconductor chip 201→the second spacer 302→the first metal layer 112→the first spacer 301→the second metal layer 122→the second semiconductor chip 202→the third spacer 303→the first metal layer 122→the first connection layer 410→the first metal layer 112→the power lead 501′ or in a reverse order thereof may be formed.

Meanwhile, referring to FIG. 7, the first connection layer 410 may be disposed in parallel to the upper substrate 110 and the lower substrate 120, and accordingly, an increase in current overlap degree may be achieved.

The first connection layer 410 may include a negative terminal N, and the third spacer 303 may extend through the first connection layer 410.

Furthermore, the second connection layer 420 may be provided. The second connection layer 420 may be disposed to be vertically spaced from the first connection layer 410 while forming a current path in a direction crossing that of a current path formed between the upper substrate 110 and the lower substrate 120 and between the first spacer 301 and the second spacer 302 by the first spacer 301 and the second spacer 302.

In the instant case, the second connection layer 420 may include remaining terminals, except for the terminals included in the first connection layer 410 and the power lead 501. That is, when the first connection layer 410 includes a negative terminal N, and the power lead 501 includes a positive terminal P, the second connection layer 420 may include an output terminal O.

Based on the above-described structure, a current loop in which current flows in an order of the power lead 501→the second metal layer 122→the first semiconductor chip 201→the second spacer 302→the first metal layer 112→the first spacer 301→the second metal layer 122→the second semiconductor chip 202→the third spacer 303→the first connection layer 410 or in a reverse order thereof may be formed. In the instant case, AC current may be output through the second connection layer 420.

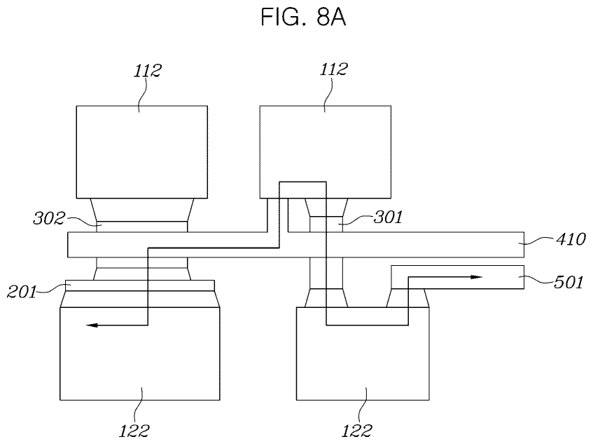

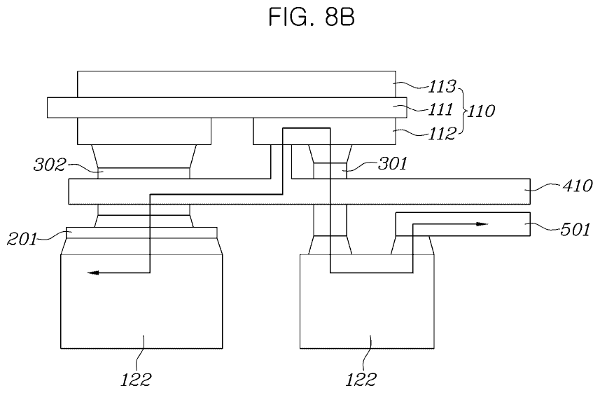

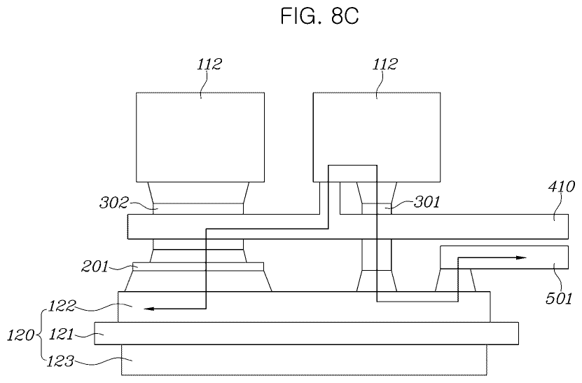

Meanwhile, such a current loop may be varied in accordance with metal layer structures of the upper substrate 110 and the lower substrate 120. This will be described hereinafter with reference to FIGS. 8A to 8C.

FIG. 8A, FIG. 8B and FIG. 8C are views explaining current loops based on different structures of the first metal layer and the second metal layer according to various exemplary embodiments of the present disclosure, respectively.

Referring to FIGS. 8A to 8C, in a power module according to an exemplary embodiment of the present disclosure, at least one of the first metal layer 112 and the second metal layer 122 may be formed by a plurality of horizontally-spaced portions. In the instant case, the first connection layer 410 may extend vertically between the first spacer 301 and the second spacer 302 so that the first connection layer 410 is electrically connected to at least one of the plural portions. In more detail, FIG. 8A and FIG. 8B show a structure in which each of the first metal layer 112 and the second metal layer 122 is formed by a plurality of horizontally-spaced portions. FIG. 8B shows a structure in which the plurality of horizontally-spaced portions of the first metal layer 122 is fixed to a single first insulating layer 111. Furthermore, FIG. 8C shows a structure in which, among the first metal layer 112 and the second metal layer 122, only the first metal layer 112 is formed by a plurality of horizontally-spaced portions, and the second metal layer 122 is formed to include an include an integrated structure.

The first connection layer 410 may extend vertically between the first spacer 301 and the second spacer 302 and electrically connected to one of the separated portions of the first metal layer 112 or the second metal layer 122. Accordingly, a current path in the same direction as that of a current path formed through the first spacer 310 and the second spacer 320 may also be formed.

Based on the above-described structures, a current loop in which current flows in an order of the power lead 501→the second metal layer 122→the first spacer 301→the first metal layer 112→the first connection layer 410→the second spacer 302→the first semiconductor chip 201→the second metal layer 122 or in a reverse order thereof may be formed.

In accordance with various embodiments of the present disclosure as described above, it may be possible to simplify a current loop of a power module through a connection layer additionally disposed between an upper substrate and a lower substrate while including a structure through which spacers extend.

Furthermore, it may be possible to enhance a current overlap effect through the current loop simplified through the connection layer.

Furthermore, it may be possible to reduce sizes of an insulation pattern and a via spacer for formation of the current loop, achieving a reduction in module size.

Furthermore, it may be possible to enhance reliability of the power module through simplification of the current loop and a reduction in module size.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”, furthermore, “one or more of A and B” may refer to “one or more of A or B” or “one or more of combinations of at least one of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
an upper substrate including a first metal layer;
a lower substrate disposed under the upper substrate, the lower substrate including a second metal layer facing the first metal layer;
a first semiconductor chip disposed on the second metal layer;
a first spacer electrically interconnecting the first metal layer and the second metal layer while extending vertically;
a second spacer electrically interconnecting the first semiconductor chip and the first metal layer while extending vertically;
a first connection layer configured to form a current path between the upper substrate and the lower substrate and between the first spacer and the second spacer in a direction crossing a direction of a current path formed by the first spacer and the second spacer; and
a power lead disposed at at least one of the first metal layer or the second metal layer.

2. The power module of claim 1, wherein the first connection layer does not overlap with the first spacer and the second spacer in a plane.

3. The power module of claim 2, wherein at least one of the first spacer or the second spacer is formed through the first connection layer.

4. The power module of claim 3, wherein the first connection layer is provided with at least one of a first through hole including a planar area corresponding to a planar area of the first spacer and through which the first spacer is penetrated or a second through hole including a planar area corresponding to a planar area of the second spacer and through which the second spacer is penetrated.

5. The power module of claim 1,
wherein at least one of the first spacer or the second spacer includes an upper portion and a lower portion, and
wherein the first connection layer is disposed to interconnect the upper portion and the lower portion of the at least one of the first spacer or the second spacer between the upper portion and the lower portion.

6. The power module of claim 1, wherein the first connection layer forms, through a pattern formed on a plane, the current path in the direction crossing the direction of the current path formed by the first spacer and the second spacer.

7. The power module of claim 6, wherein the pattern is formed through a combination of a plurality of separated panels disposed in parallel while being horizontally spaced apart from one another.

8. The power module of claim 1, wherein the first connection layer has a vertical thickness greater than or equal to a vertical thickness of the power lead.

9. The power module of claim 1, wherein the first connection layer includes:
a substrate-corresponding portion overlapping with the upper substrate and the lower substrate at at least a portion thereof in a plane; and
a lead-corresponding portion extending from the substrate-corresponding portion to protrude outwardly of the upper substrate and the lower substrate in the plane, the lead-corresponding portion allowing current to be input thereto and to be output therefrom.

10. The power module of claim 9,
wherein the lead-corresponding portion includes one of a positive terminal, a negative terminal, and an output terminal or is connected to one of the positive terminal, the negative terminal, and the output terminal, and
wherein the power lead includes one of remaining ones of the positive terminal, the negative terminal, and the output terminal.

11. The power module of claim 10, further including:
a second connection layer disposed to be vertically spaced apart from the first connection layer and configured to form a current path between the upper substrate and the lower substrate and between the first spacer and the second spacer in the direction crossing the direction of the current path formed by the first spacer and the second spacer,
wherein the second connection layer includes another one of the remaining ones of the positive terminal, the negative terminal, and the output terminal or is connected to the other one of the remaining ones of the positive terminal, the negative terminal, and the output terminal.

12. The power module of claim 9, wherein the lead-corresponding portion is upwardly spaced apart from the power lead to overlap with the power lead in the plane.

13. The power module of claim 9, wherein the lead-corresponding portion is bent downwardly from the substrate-corresponding portion and extends outwardly of the upper substrate and the lower substrate so that the lead-corresponding portion is disposed in parallel to the power lead while being horizontally spaced apart from the power lead.

14. The power module of claim 9, wherein the substrate-corresponding portion is disposed in parallel to the upper substrate and the lower substrate while being vertically spaced apart from the upper substrate and the lower substrate.

15. The power module of claim 1, further including:
a third spacer disposed to be horizontally spaced apart from the second spacer, the first spacer being disposed between the second spacer and the third spacer,
wherein the first connection layer is bonded to at least one of the upper substrate, the lower substrate, the first spacer, the second spacer, or the third spacer.

16. The power module of claim 15, wherein the first connection layer does not overlap with the third spacer in a plane.

17. The power module of claim 16, wherein the first connection layer is bent upwardly or downwardly between the first spacer and the third spacer and bonded to the upper substrate or the lower substrate.

18. The power module of claim 16, wherein the third spacer is formed through the first connection layer.

19. The power module of claim 16, wherein the first connection layer is horizontally bonded to a side surface of the third spacer.

20. The power module of claim 1,
wherein at least one of the first metal layer or the second metal layer is formed by a plurality of horizontally-spaced portions, and
wherein the first connection layer extends vertically between the first spacer and the second spacer and electrically connected to at least one of the plurality of portions.
